(19) United States
(12) Patent Application Publication
(10) Pub. No.: US 2011/0193854 A1
(43) Pub. Date: Aug. 11, 2011

(54) SYNCHRONOUS BUS DRIVING METHOD

(75) Inventor: Yongman Lee, Pleasanton, CA (US)

(73) Assignee: APPLE INC., Cupertino, CA (US)

(21) Appl. No.: 12/839,121

(22) Filed: Jul. 19, 2010

Related U.S. Application Data
(60) Provisional application No. 61/303,530, filed on Feb. 11, 2010.

(51) Int. Cl. G06F 3/038; H03K 17/16

(52) U.S. Cl. 345/214; 326/29

(57) ABSTRACT

Techniques are provided for synchronizing the data signals transmitted through a synchronous bus in a display device. One embodiment includes manipulating the clock signals and/or data signals transmitted by a display controller in the display based on the location on the bus where a data signal is to be transmitted. For example, a pre-emphasized clock signal having a higher initial voltage level may be used for a data signal transmitted farther on the bus from the display controller. The pre-emphasized clock signal may compensate for propagation delays associated with transmitting the data signal through the bus. Further, a de-emphasized clock signal may be used for data signals transmitted to a section on the bus closer on to the display controller, and neutral clock signals may be used for data signals transmitted to a section that is of intermediate distance from the display controller.

### CROSS-REFERENCE TO RELATED APPLICATIONS

This application claims the benefit of U.S. Provisional Patent Application No. 61/303,530, entitled “Synchronous Bus Driving Method,” filed Feb. 11, 2010, which is herein incorporated by reference.

### BACKGROUND

The present disclosure relates generally to electronic devices, and more particularly, to clock signal driving techniques for such devices.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Liquid crystal displays (LCDs) are commonly used as screens or displays for a wide variety of electronic devices, including such consumer electronics as televisions, computers, and handheld devices (e.g., cellular telephones, audio and video players, gaming systems, and so forth). Such LCD devices typically provide a flat display in a relatively thin and low weight package that is suitable for use in a variety of electronic goods. In addition, such LCD devices typically use less power than comparable display technologies, making them suitable for use in battery powered devices or in other contexts where it is desirable to minimize power usage.

LCD devices typically include thousands (or millions) of picture elements, i.e., pixels, arranged in a matrix of rows (also referred to as “scanning lines” and columns (also referred to as “data lines”). For any given pixel of an LCD device, the amount of light viewable on the LCD depends on the voltage driven to the pixel. The pixels may be driven by scanning line and data line circuitry to display an image that may be perceived by a user. Typically, LCDs include driving circuitry for converting digital image data into analog voltage values which may be supplied to pixels within a display panel of the LCD. The driving circuitry may receive clock signals and data signals from a display controller via a bus, and may use such signals in driving the pixels of the LCD. For example, the driving circuitry may receive the data signal from the display controller, and may latch data based on the rising edge and/or falling edge of the clock signal.

As current LCD devices may have a large display area having a large matrix of pixels, data signals and clock signals may be transmitted over a relatively long bus to reach all the data lines of the display. Due to resistive-capacitive (RC) characteristics and/or electromagnetic interference from the bus, signals may increasingly degrade as they are transmitted through the length of the bus. For example, a clock signal may generally be a square wave having steep edges, and data may be latched at the rising and/or falling edges. However, a clock signal that is transmitted through a long bus may degrade due to the RC effects, and may have an increasingly sloped, rather than a square waveform. The sloped waveform of a degraded clock signal may cause data to be latched later, or not at all.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

The present disclosure relates generally to techniques for transmitting signals over a synchronous bus in an electronic system. One embodiment includes manipulating the clock signals and/or data signals transmitted to the driving circuitry of an electronic component based on the location on a data bus where the signals are to be driven. For example, a controller may transmit signals via a synchronous bus to the driving circuitry which provides data signals to many data lines in an electronic device. As clock signals may be degraded due to the resistive-capacitive (RC) characteristics and/or electromagnetic interference of the bus, the clock signals transmitted farther distances along the bus relative to the controller may result in increased data latching delays or failure, compared to clock signals transmitted to shorter distances along the bus.

In one embodiment, a clock signal having a higher initial voltage (referred to as a “pre-emphasized clock signal”) may be transmitted over a relatively far distance along a bus to compensate for possible degradation of the clock signal as it flows through the length of the bus. Further, a clock signal having a lower initial voltage (referred to as a “de-emphasized clock signal”) may be transmitted to relatively short distances along the bus, as the de-emphasized clock signals travelling a shorter distance along the bus may not be as affected by the RC effects and/or interference throughout the entire length of the bus. A normal square wave clock signal (which is neither pre-emphasized or de-emphasized) may be transmitted to an intermediate distance on the bus. In some embodiments, the use of pre-emphasized and/or de-emphasized clock signals may reduce data latching delays and/or electromagnetic interference along a synchronous bus while also possibly reducing power consumption.

### BRIEF DESCRIPTION OF THE DRAWINGS

Various aspects of this disclosure may be better understood upon reading the following detailed description and upon reference to the drawings in which:

FIG. 1 is a block diagram depicting exemplary components of an electronic device, in accordance with aspects of the present disclosure;

FIG. 2 is a front view of a handheld electronic device, in accordance with aspects of the present disclosure;

FIG. 3 is a view of a computer, in accordance with aspects of the present disclosure;

FIG. 4 is a circuit diagram showing a synchronous data bus transmitting data and clock signals to switching and display driving circuitry that may be used in conjunction with an LCD display panel, in accordance with aspects of the present disclosure;

FIG. 5 is a diagram depicting a single-edged clock signal and a corresponding data signal, in accordance with aspects of the present disclosure;

FIG. 6 is a diagram depicting a dual-edged clock signal and a corresponding data signal, in accordance with aspects of the present disclosure;

FIG. 7 is a circuit diagram illustrating an example of various sections of a synchronous bus in an LCD display panel, in accordance with aspects of the present disclosure;

FIG. 8 is a diagram depicting examples of de-emphasized, neutral, and pre-emphasized clock signals which may be used in the synchronous bus illustrated in FIG. 7, in accordance with aspects of the present disclosure;

FIG. 9 is a circuit diagram showing a dual-edged clock generator used for generating clock signals, in accordance with aspects of the present disclosure;

FIG. 10 is a set of timing diagrams depicting the corresponding clock signals produced in different operations of the clock generator illustrated in FIG. 9, in accordance with aspects of the present disclosure;

FIG. 11 is a circuit diagram showing a single-edged clock generator used for generating clock signals, in accordance with aspects of the present disclosure;

FIG. 12 is a circuit diagram depicting an analog equivalent for the clock generator illustrated in FIG. 9, in accordance with aspects of the present disclosure; and

FIG. 13 is a diagram depicting a signal produced in response to different inputs of the circuit illustrated in FIG. 12.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be open-ended and inclusive and mean that there may be additional elements other than the listed elements.

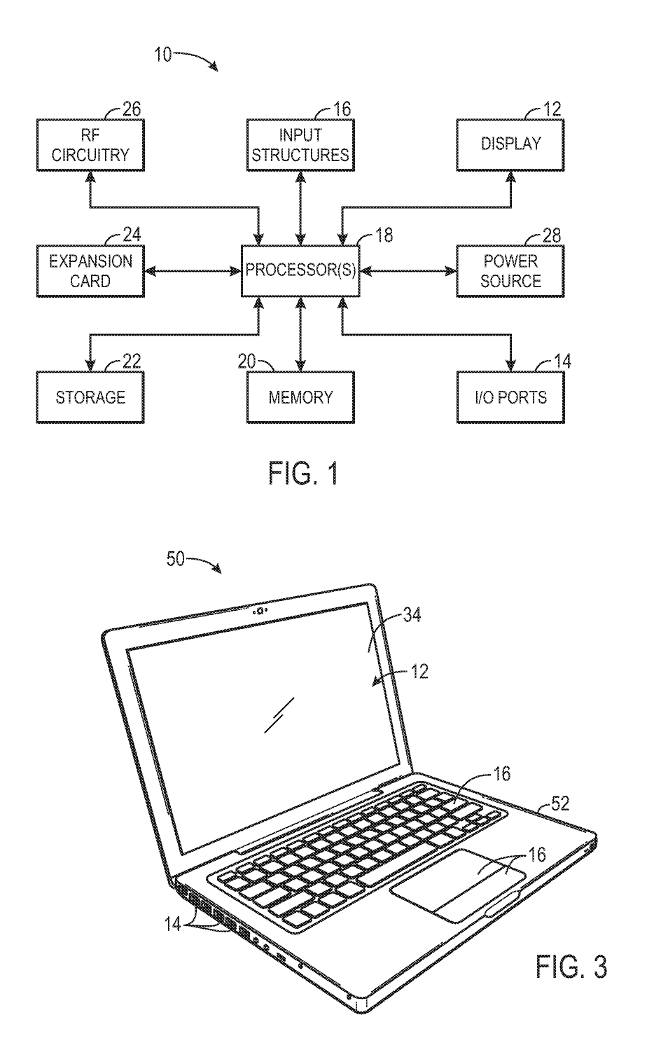

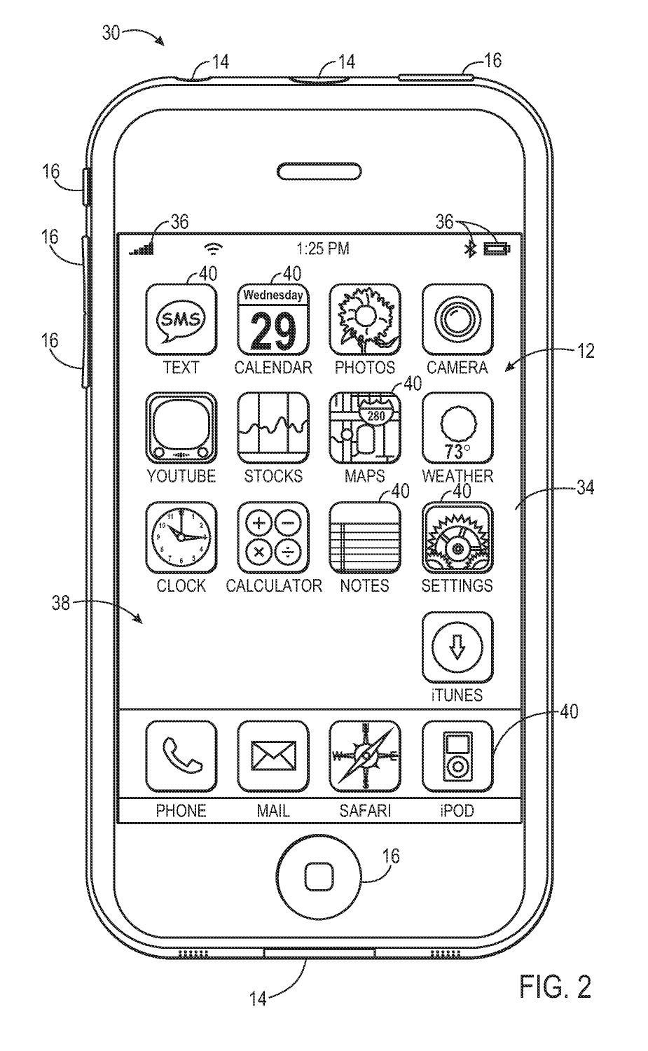

With these foregoing features in mind, examples for suitable electronic systems that may implement a synchronous bus in accordance with aspects of the present disclosure are provided below. While the given examples apply generally to display devices, it should be noted that the present disclosure is not limited to display devices. The techniques for transmitting data through a synchronous bus may be applied to various electronic systems which transmit signals through a synchronous bus. In FIG. 1, a block diagram depicting various components that may be present in electronic devices suitable for use with the present techniques is provided. In FIG. 2, one example of a suitable electronic device, provided here as a handheld electronic device, is depicted. In FIG. 3, another example of a suitable electronic device, provided here as a computer system, is depicted. These types of electronic devices, and other electronic devices providing comparable display capabilities, may be used in conjunction with the present techniques.

An example of a suitable electronic device may include various internal and/or external components which contribute to the function of the device. FIG. 1 is a block diagram illustrating the components that may be present in such an electronic device 10 and which may allow the device 10 to function in accordance with the techniques discussed herein. Those of ordinary skill in the art will appreciate that the various functional blocks shown in FIG. 1 may comprise hardware elements (including circuitry), software elements (including computer code stored on a computer-readable medium) or a combination of both hardware and software elements. It should further be noted that FIG. 1 is merely one example of a particular implementation and is merely intended to illustrate the types of components that may be present in a device 10. For example, in the presently illustrated embodiment, these components may include a display 12, I/O ports 14, input structures 16, one or more processors 18, a memory device 20, a non-volatile storage 22, expansion card(s) 24, RF circuitry 26, and a power source 28.

The processor(s) 18 may control the general operation of the device 10. For instance, the processor(s) 18 may provide the processing capability to execute an operating system, programs, user and application interfaces, and any other functions of the electronic device 10. As will be appreciated, the processor(s) 18 may be coupled to one or more data buses for transferring data and instructions between various components of the device 10. The present techniques for transmitting over a synchronous bus may be implemented on the data and instructions transfers over the data buses.

The instructions or data to be processed by the processor(s) 18 may be stored in a computer-readable medium, such as a memory 20. Such a memory 20 may be provided as a volatile memory, such as random access memory (RAM) or as a non-volatile memory, such as read-only memory (ROM), or as a combination of one or more RAM and ROM devices. The memory 20 may store a variety of information and may be used for various purposes. For example, the memory 20 may store firmware for the electronic device 10, such as a basic input/output system (BIOS), an operating system, various programs, applications, or any other routines that may be executed on the electronic device 10, including user interface functions, processor functions, and so forth. The memory 20 may also be used for buffering or caching during operation of the electronic device 10. Furthermore, the memory 20 may include a bus used for transmitting information to and from the memory 20 and other components of the device 10. In some embodiments, signal waveform modification techniques may be implemented in signal transmission over the memory bus.

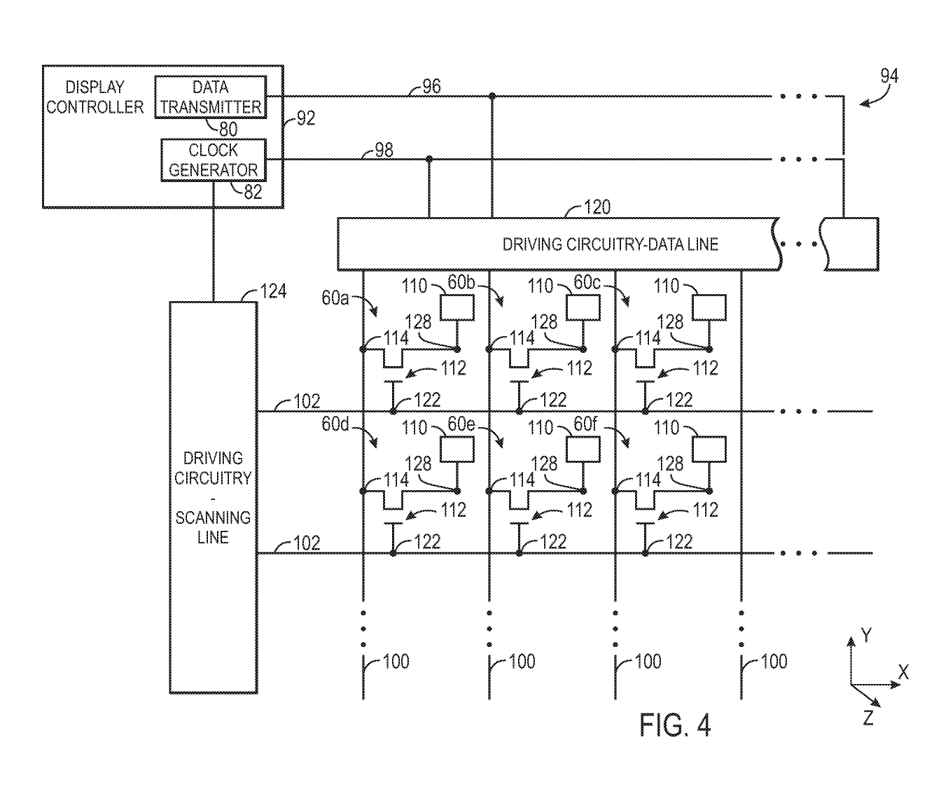

The display 12 may be used to display various images generated by the electronic device 10. In one embodiment, the display 12 may be a liquid crystal display (LCD). For example, the display 12 may be an LCD employing fringe field switching (FFS), in-plane switching (IPS), or other techniques useful in operating such LCD devices. Additionally, in certain embodiments of the electronic device 10, the display 12 may be provided in conjunction with a touch-sensitive element, such as a touchscreen, that may be used as part of the control interface for the device 10. The display 12 may include a matrix of pixels and circuitry for modulating the transmittance of light through each pixel to display an image. A more detailed example of such display circuitry is provided in FIG. 4.

In certain embodiments, an input structure 16 and display 12 may be provided together, such as in the case of a touchscreen where a touch-sensitive mechanism is provided in conjunction with the display 12. In such embodiments, the user may select or interact with displayed interface elements via the touch-sensitive mechanism. In this way, the displayed interface may provide interactive functionality, allowing a user to navigate the displayed interface by touching the display 12. For example, user interaction with the input structures 16, such as to interact with a user or application interface displayed on the display 12, may generate electrical signals indicative of the user input. These input signals may be routed via suitable pathways, such as an input hub or data bus, to the one or more processors 18 for further processing.

The electronic device 10 may also take the form of other types of devices, such as mobile telephones, media players, personal data organizers, handheld game platforms, cameras, and/or combinations of such devices. For example, FIG. 2 illustrates an electronic device 10 in the form of a portable handheld device 30, provided here as a cellular telephone. Various embodiments of the handheld device 30 may incorporate the functionalities of one or more types of devices, such as a cellular phone function, a digital media player, a camera, a portable gaming platform, a personal data organizer, or some combination thereof. By way of example, the handheld device 30 may be a model of an iPod®, iPod® Touch, or iPhone® available from Apple Inc.

In the illustrated embodiment, the handheld device 30 includes the above-discussed display 12 in the form of a liquid crystal display (LCD) 34. The LCD 34 may display various images generated by the handheld device 30. For example, the LCD 34 may display various system indicators 36 that provide feedback to a user with regard to one or more states of the handheld device 30, such as power status, signal strength, call status, external device connections, and so forth. The LCD 34 may also be configured to display a graphical user interface (“GUI”) 38 that allows a user to interact with the handheld device 30. The GUI 38 may include various layers, windows, screens, templates, or other graphical elements that may be displayed in all, or a portion, of the LCD 34. Generally, the GUI 38 may include graphical elements that represent applications and functions of the electronic device. The graphical elements may include icons 40 and other images representing buttons, sliders, menu bars, and the like. The icons 40 may correspond to various applications of the electronic device that may open or execute upon detecting a user selection of a respective icon 40. In some embodiments, the selection of an icon 40 may lead to a hierarchical navigation process, such that selection of an icon 40 leads to a screen that includes one or more additional icons or other GUI elements. As will be appreciated, the icons 40 may be selected via a touchscreen included in the display 12, or may be selected by a user input structure 16, such as a wheel or button.

In addition to handheld devices 30, such as the depicted cellular telephone of FIG. 2, an electronic device 10, in accordance with embodiments of the present invention, may also take the form of a computer or other type of electronic device. For instance, such computers may include computers that are generally portable (such as laptop, notebook, and tablet computers) as well as computers that are generally non-portable (such as conventional desktop computers, workstations and/or servers). In certain embodiments, the electronic device 10 in the form of a computer may be a model of a MacBook®, MacBook® Pro, MacBook Air®, iMac®, Mac® mini, or PowerBook® available from Apple Inc. In another embodiment, the electronic device 10 may take the form of a portable multi-function tablet computing device such as the iPad® tablet computer, also available from Apple Inc. By way of example, an electronic device 10 in the form of a laptop computer 50 is illustrated in FIG. 3 in accordance with one embodiment of the present invention. The depicted computer 50 includes a housing 52, the display 12 (such as LCD 34), the input structures 16, and the I/O ports 14.

With the foregoing discussion in mind, it may be appreciated that an electronic device 10 in either the form of a handheld device 30 (FIG. 2) or a computer 50 (FIG. 3) may be provided with a display device 10 in the form of an LCD 34. As discussed above, an LCD 34 may be utilized for displayed respective operating system and/or application graphical user interfaces running on the electronic device 10 and/or for displaying various data files, including textual, image, video data, or any other type of visual output data that may be associated with the operation of the electronic device 10.

Continuing now to FIG. 4, a schematic circuit representation of pixel driving circuitry found in an LCD 34 is shown. For example, such circuitry may be embodied in a thin film transistor (TFT) layer of an LCD 34. The TFT layer may generally form the electrical devices and pathways which drive operation a unit pixel 60. In one embodiment, the pathways to a unit pixel 60 may include the respective “source lines”), scanning lines (also referred to as “gate lines”), pixel electrodes, and common electrodes (as well as other conductive traces and structures) of the pixel 60. Such conductive structures may, in light-transmissive portions of the pixel 60, be formed using transparent conductive materials, such as indium tin oxide (ITO) or indium zinc oxide (IZO).

As depicted in FIG. 4, a plurality of unit pixels 60 may be disposed in a pixel array or matrix defining a plurality of rows and columns of unit pixels that collectively form an image display region of an LCD 34. In such an array, each unit pixel 60 may be defined by the intersection of rows and columns, which may be defined by the illustrated data (or “source”) lines 100 and scanning (or “gate”) lines 102, respectively. Although only six unit pixels, referred to individually by the reference numbers 60a-60f, respectively, are shown in the present example for purposes of simplicity, it should be understood that in an actual LCD implementation, each data line 100 and scanning line 102 may include hundreds or even thousands of unit pixels. By way of example, in a color LCD panel 34 having a display resolution of 960×640, each data line 100, which may define a column of the pixel array, may include 640 unit pixels, while each scanning line 102, which may define a row of the pixel array, may include 960 groups of pixels, wherein each group has a red, blue, and green pixel, thus totaling 2880 unit pixels per scanning line 102. In the present illustration, the group of unit pixels 60a-60c may represent a group of pixels having a red pixel (60a), a blue pixel (60b), and a green pixel (60c). The group of unit pixels 60d-60f may be arranged in a similar manner.

As shown in the present figure, each unit pixel 60 includes a pixel electrode 110 and thin film transistor (TFT) 112 for switching the pixel electrode 110. In the depicted embodiment, the source 114 of each TFT 112 is electrically connected to a source or data line 100, extending from respective source line driving circuitry 120. Similarly, in the depicted embodiment, the gate 122 of each TFT 112 is electrically connected to a gate or scanning line 102, extending from respective gate line driving circuitry 124. In the depicted embodiment, the pixel electrode 110 is electrically connected to a drain 128 of the respective TFT 112.

In one embodiment, the source line driving circuitry 120 may send image signals to the pixels 60 by way of the respective data lines 100. Such image signals (also referred to as “data signals”) may be applied by line-sequence. That is, the data lines 100 (defining columns) may be sequentially activated during operation of the LCD 34. For example, the data line driving circuitry 120 may drive a data signal based on a clock signal which synchronizes the data signal driven down the data lines 100. The scanning lines 102 (defining rows) may apply scanning signals from the gate line driving circuitry 124 to the respective gates 122 of each TFT 112 to which the respective scanning lines 102 are connected. Such scanning signals may be applied by line-sequence with a predetermined timing and/or in a pulsed manner.

Each TFT 112 serves as a switching element which may be activated and deactivated (e.g., turned on and off) for a predetermined period based upon the respective presence or absence of a scanning signal at the gate 122 of the TFT 112. When activated, a TFT 112 may store the image signals received via a respective data line 100 as a charge in the pixel electrode 110 with a predetermined timing. The image signals stored by the pixel electrode 110 may be used to generate an electrical field between the respective pixel electrode 110 and a common electrode (not shown in FIG. 4). Such an electrical field may align liquid crystals molecules within the LCD 34 to modulate light transmission. In some embodiments, a storage capacitor (not shown) may also be provided in parallel to the liquid crystal capacitor formed between the pixel electrode 110 and the common electrode to prevent leakage of the stored image signal by the pixel electrode 110. For example, such a storage capacitor may be provided between the drain 128 of the respective TFT 112 and a separate capacitor line.

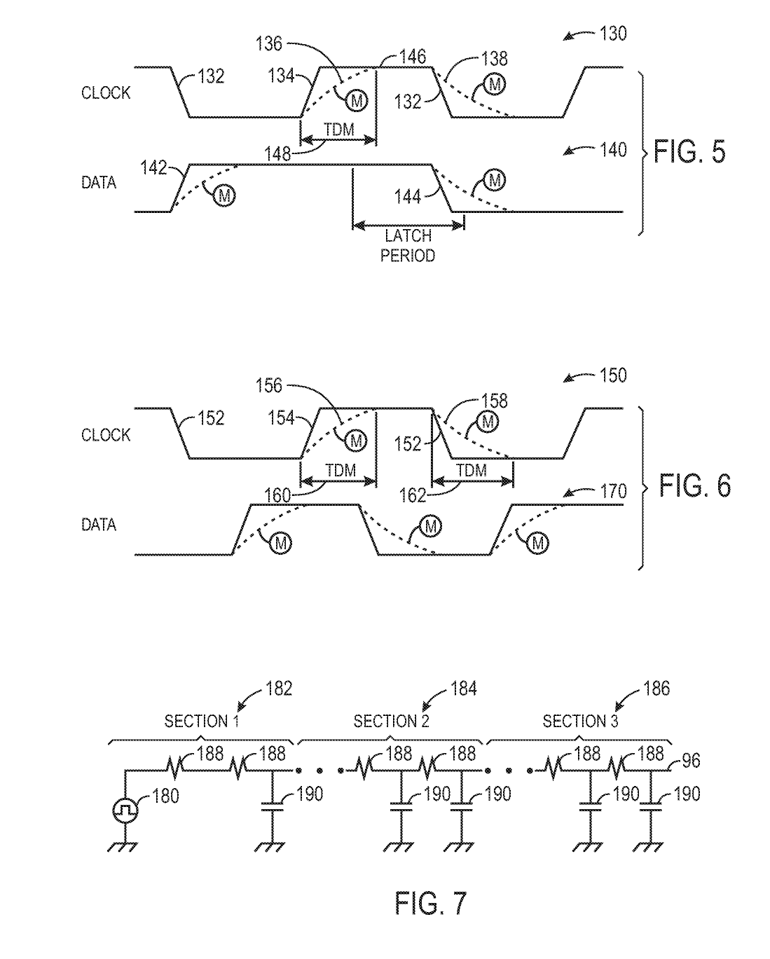

As depicted in FIG. 4, data signals and clock signals may be provided to the data line driving circuitry 120 by the display controller 92. The display controller 92 may include a data transmitter 80 and a clock generator 82 for generating the data signals and clock signals, respectively. The generated data signals and clock signals may be provided to the driving circuitry 120 via a synchronous bus 94. As illustrated, the synchronous bus 94 (also referred to as a data bus) may be shared by n number of data lines 96 (e.g., 48 data lines) and clock lines 98. Further, although FIG. 5 depicts the synchronous bus 94 as a shared bus, the synchronous bus 94 may instead have a point-to-point bus interface. In some embodiments, the clock generator 82 may also provide a clock signal to the scanning line driving circuitry 124 to synchronize the scanning of the scanning lines 102.

Diagrams illustrating examples of clock signals and corresponding data signals that may be transmitted over bus 94 are provided in FIGS. 5 and 6. A single-edged clock signal 130 and a corresponding data signal 140 are illustrated in FIG. 5, and a dual-edged clock signal 150 and a corresponding data signal 170 are illustrated in FIG. 6. The waveform of the clock signals and data signals illustrated in FIGS. 5 and 6 are merely explanatory for the present disclosure, and some embodiments of the present techniques may employ clock signals having different waveforms from the illustrated signals.

The single-edged clock signal 130 illustrated in FIG. 5 may be produced by a clock generator 82 (FIG. 4) and used to assert and latch data on data lines 96. The single-edged clock signal 130 may include a waveform having falling edges 132 and rising edges 134. The single-edged clock signal 130 may assert data the falling edges 132 and latch data on the rising edges 134. Asserting data at the falling edges 132 may be shown by the rising edge 142 and falling edge 144 of the data signal 140.

A dual-edged clock signal 150 and a corresponding data signal 170 are provided in FIG. 6. The dual-edged clock signal 150 may also be used to assert and latch data on data lines 96. The dual-edged clock signal 150 may include a waveform having falling edges 152 and rising edges 154. The dual-edged clock signal 150 may assert data between the falling edges 152 and rising edges 154 and latch data on the falling edges 152 and rising edges 154, as shown by the corresponding data signal 170.

The latching of data in response to a clock signal may begin when the clock signal rises to some threshold logic level. Therefore, clock signals may generally have a waveform with steep edges, such as a square wave, where a rising edge or falling edge of the clock signal may automatically reach a logic high or a logic low threshold. However, clock signals transmitted through relatively long bus lines may be impacted by the RC effect of the bus and become undesirably sloped. As a dual-edged clock signal 150 propagates through m nodes of a synchronous bus, the waveform of the clock signal 150 at node m (which may be the node farthest from the display controller 92 in FIG. 4) may become increasingly sloped. For example, such sloped clock signal characteristics may be represented by the dotted segments 136 and 138 of the single-edged clock signal 130 and segments 156 and 158 of the dual-edged clock signal 150. The dotted segments (e.g., segments 136, 138, 156, and 158) have been labeled m to represent how a clock signal and/or a data signal may appear by the time signals reach node m of the synchronous bus.

Slopes in the clock signal 150 may lead to delays in data latching. For example, if the clock signal 150 at node m sloped (e.g., sloped rise 156) to reach a threshold logic level 164, data may not latch until the threshold level 164 is reached. This may result in data latching delays 160 and 162 compared to data latching at a node close to the display controller, and in some instances, data may fail to latch due to clock signal degradations.

The circuit diagram of FIG. 7 represents losses on the bus 94 in an electronic component (e.g., an LCD 34) due to RC effects and/or other transmission line effects. The signal generator 180 may be the source of the clock signal or a data signal. For instance, using a display device as an example, the signal generator 180 may be located within the display controller 92 (FIG. 4) of an LCD 34. A bus 94 may experience various parasitic resistances 188 and parasitic capacitances 190 that impact the integrity of the data signal in proportion to the length of the bus 94 traveled.

For example, the bus 94 is illustrated in three sections in FIG. 7 to represent the signal losses on the bus 94 which may be proportional to the length of the bus 94 through which a signal is transmitted. A section of the bus 94 that is nearest to the signal generator 180 (i.e., nearest section 182) may substantially retain signal integrity, and a section of the bus 94 that is farthest from the signal generator 180 (i.e., farthest section 186) may have reduced signal integrity as signals are transmitted farther down the length of the bus 94. For example, while clock signals may have steep edges close to the signal generator 180, the edges of the clock signals may become decreasingly sloped farther away from the signal generator 180. A section of the bus 94 that is of intermediate distance (relative to sections 182 and 186) from the signal generator 180 (i.e., intermediate section 184) may receive a signal with an intermediate amount of degradation relative to the nearest section 182 and the farthest section 186.

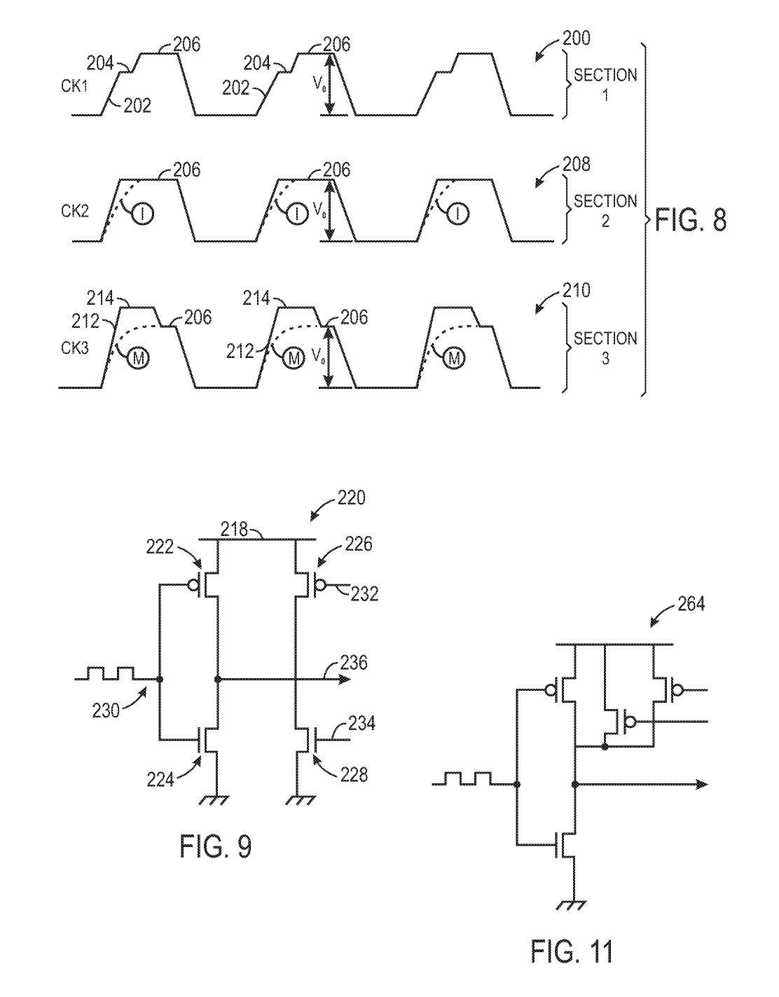

The clock signal diagrams illustrated in FIG. 8 provide one embodiment of how clock signals may be manipulated based on the travel length along the bus 92. In one embodiment, the clock signals transmitted through the bus 92 may be manipulated depending on where in the bus 92 the clock signal is to be driven. For example, the clock signal driven to the nearest section 182 (FIG. 7) of a bus 94 may be clocked using a de-emphasized clock signal 200. The de-emphasized clock signal 200 may have a “de-emphasized” rising edge 202 that initially reaches and remains at a voltage value 204 below a final voltage value (V₀) 206. Each logic high period of the de-emphasized clock signal 200 may output the voltage value 204 for a substantial period of time before rising to the final voltage value (V₀) 206. As the de-emphasized clock signal 200 may not be substantially effected by transmission line effects of the bus 94, the de-emphasized clock signal 200 the resulting data may still be synchronized with other (later) nodes of the bus 92 receiving a neutral (not de-emphasized) clock signal. For example, the data signal driven to the intermediate section 184 of a data line may be clocked using a neutral clock signal 208 which rises to and falls from the final voltage value (V₀) 206. The neutral clock signal 208 may reach a threshold logic level of a driving circuit more quickly than the de-emphasized clock signal 200 for each rising edge of the signals, but due to the decreased sloping (indicated by the dotted lines marked I) of the neutral clock signal 208 due to the increased transmission line effects of the bus 94 transmitting to the intermediate section 184, the data signals transmitted to the nearest section 182 and the intermediate section 184 may still be synchronized.

The clock signal driven to the farthest section 186 of a data line 96 may be clocked using a pre-emphasized clock signal 210. The pre-emphasized clock signal 210 may have a “pre-emphasized” rising edge 212 which rises to a voltage level 214 exceeding the final voltage level (V₀) 206. Each logic high period of the pre-emphasized clock signal 210 may output at the voltage level 214 for a substantial period of time before falling to the final voltage value (V₀) 206. The higher voltage 214 reached by the rising edge 212 may enable the pre-emphasized clock signal 210 to rise more steeply than a de-emphasized clock signal 200. The relatively steeper rise of the pre-emphasized clock signal 210 may also decay more gradually as compared to the neutral clock signal 208. The more gradual decay of the pre-emphasized clock signal 210 may result in the farthest section 186 receiving a clock signal which is comparable (having substantially similar rising and/or falling edges) to the clock signal received by the nearest section 182 and/or intermediate section 184. For example, the more gradual decay, as represented by the dotted line marked M, may reach a threshold 206 substantially synchronously with the de-emphasized signal 200 which experiences little degradation and the neutral signal 208 which experiences comparatively less degradation than the pre-emphasized signal 210. Thus, by using a combination of clock signal manipulations, such as pre-emphasis of the clock signal 200 for driving a data signal of the farthest section 186 and de-emphasis of the clock signal 210 for driving a data signal of the nearest section 182, signal integrity may be maintained even for data signals transmitted to the farthest section 186 of a synchronous bus.

While three types of clock signals are provided in FIG. 8 for each of the three sections illustrated in FIG. 7, in some embodiments, any combination of clock signals may be modified for transmission to different sections of a synchronous bus. For example, in one embodiment, a synchronous bus may be divided into two sections, and a neutral clock signal may be applied to one section while a pre-emphasized clock signal may be applied to another section. In another embodiment, a synchronous bus may be divided into more than three sections, using different combinations or amplitudes for clock signal pre-emphasis and/or de-emphasis to synchronize a signal to each of the sections of the bus.

Embodiments of de-emphasizing and pre-emphasizing clock signal may also reduce power consumption. For example, a conventional technique may involve increasing the voltage amplitude of the clock signals such that the change in logic level of the clock signal may be faster identified by the driving circuitry (e.g., the threshold level of the driving circuitry may be reached more quickly). However, by using such a technique, the overall power consumption is increased, as more power must be used to increase the amplitudes of clock signals. In the present embodiments, the pre-emphasis of clock signals increases the amplitude of the clock signal only initially after the rising edge 212 and may not consume as much power as an overall increase in the voltage amplitude of the clock signal. Additionally, in some embodiments, de-emphasis of clock signals for generating data signals driven to the nearest section 182 may further decrease power consumption.

Furthermore, in some embodiments, the frequency spread of the display logic may be improved by reducing the spectral density of the electromagnetic interference generated by the clock signals. For examples, using one clock signal may generally result in a narrow frequency spectrum. However, additional harmonics may be introduced to pre-emphasize and/or de-emphasize to different clock signals transmitted through a synchronous bus. By using additional harmonics, the frequency spectrum of the electronic component may be increased. In some embodiments, increasing the frequency spectrum may reduce electromagnetic interference in the electronic system.

FIG. 9 is a circuit diagram showing an example of a dual-edged clock generator 82a which may be used to generate clock signals such as the signals in FIG. 8, in accordance with an embodiment. The dual-edged clock generator 82a may be one embodiment of the clock generator 82 illustrated in FIG. 4. A set of diagrams including voltage levels used to drive the clock generator 82a of FIG. 9 and corresponding clock signal outputs is provided in FIG. 10. FIGS. 9 and 10 will be discussed concurrently to explain the function and outputs of the clock generator 82a with respect to the voltages used to drive it.

The dual-edged clock generator 82a may include four transistors, with two PMOS transistors 222 and 226 and two NMOS transistors 224 and 228. Any suitable oscillator, such as a crystal oscillator, may provide the signal input to the clock generator 82a. Depending on the voltage applied at the input node 230, the gate 232 of the PMOS transistor 226, and the gate 234 of the NMOS transistor 228, the clock signal output at the output node 236 may be manipulated to form de-emphasized, neutral, and/or pre-emphasized clock signals.

Beginning first with an explanation on outputting a neutral clock signal 242 (e.g., without pre-emphasis or de-emphasis) from the clock generator 82a, the PMOS transistor 226 and NMOS transistor 228 may be deactivated by driving a high voltage to the gate 232 of the PMOS transistor 226 and a low voltage to the gate 234 of the NMOS transistor 228. With the PMOS transistor 226 and NMOS transistor 228 deactivated and in a high resistance state, the voltage applied at the input node 230 will either activate or deactivate the PMOS transistor 222 and NMOS transistor 224. A high voltage level at the input node 230 may result in a high resistance state in the PMOS transistor 222 and a low resistance state in NMOS transistor 224. As the voltage may be blocked by the PMOS transistor 222 and passed by the NMOS transistor 224, the voltage may be drawn to the ground, such that the output response to a high voltage signal applied at the input node 230 may be a low voltage output from the output node 236. A low voltage level at the input node 230 may result in a low resistance state in the PMOS transistor 222 and a high resistance state in the NMOS transistor 224. As voltage may be blocked by the NMOS transistor 224 and passed by the PMOS transistor 222, the voltage may flow from the supply line 218 to the output node 236, such that the output response to a low voltage signal may be a high voltage output from the node 236. This relationship may be further illustrated in the voltage signal 240 and corresponding neutral clock signal 242 generated by the clock generator circuitry 82a. A rising edge of the voltage signal 240 input into the node 230 may result in a falling edge output of the clock signal from the output node 236.

In one embodiment, to generate a clock signal with pre-emphasis or de-emphasis, the PMOS transistor 226 or NMOS transistor 228 may be activated. Again, the signal 240 may be used as an example of voltage levels applied at the input node 230. The activation of the PMOS transistor 226 may be synchronized with an activation of the PMOS transistor 222. The activation of the PMOS transistor 226 may be for a shorter time duration than the activation of the PMOS transistor 222. The shorter activation of the PMOS transistor 226 may contribute to an increased voltage to the initial portion of a logic high of the pre-emphasized clock signal 250. The PMOS transistor 226 (which may be deactivated by a high voltage to generate a neutral clock signal 242) may be activated by driving a low input voltage (indicated by the falling edge 248) in the signal 246 applied at the gate 232 of the PMOS transistor 226. The resulting voltage may produce a pre-emphasized clock signal 250 where the pre-emphasized rising edge initially reaches a voltage 252 higher than the voltage of the neutral signal 242.

Similarly, to generate a de-emphasized clock signal 258, the activation of the NMOS transistor 228 may be synchronized with an activation of the PMOS transistor 222. The activation of the NMOS transistor 228 may be for a shorter time duration than the activation of the PMOS transistor 222. The shorter activation of the NMOS transistor 228 may result in a decreased voltage in the initial portion 260 of a logic high of the de-emphasized clock signal 258. The NMOS transistor 228 (which may be deactivated by a low voltage to generate the neutral clock signal 242) may be activated by driving a high input voltage (indicated by the rising edge 256) in the signal 254 applied at the gate 234 of the NMOS transistor 228. Due to the activation of the NMOS transistor 228, an initial portion of the logic high of a de-emphasized clock signal 258 will have a lower voltage level 260 than the final voltage level 262.

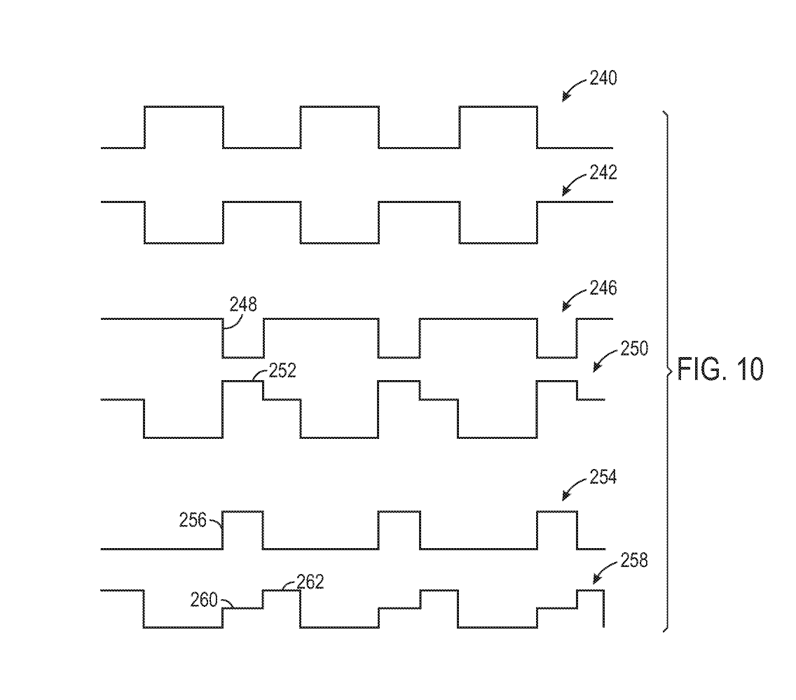

FIG. 11 illustrates another example of a clock generator which may be used to manipulate clock signals to synchronize the transmission of a data signal through a data line. In particular, FIG. 11 illustrates an example of a single-edged clock generator 82b. As with the dual-edge clock generator 82a discussed in FIG. 9, the single edge-clock generator 82b may also be used to generate pre-emphasized, neutral, and/or de-emphasized clock signals.

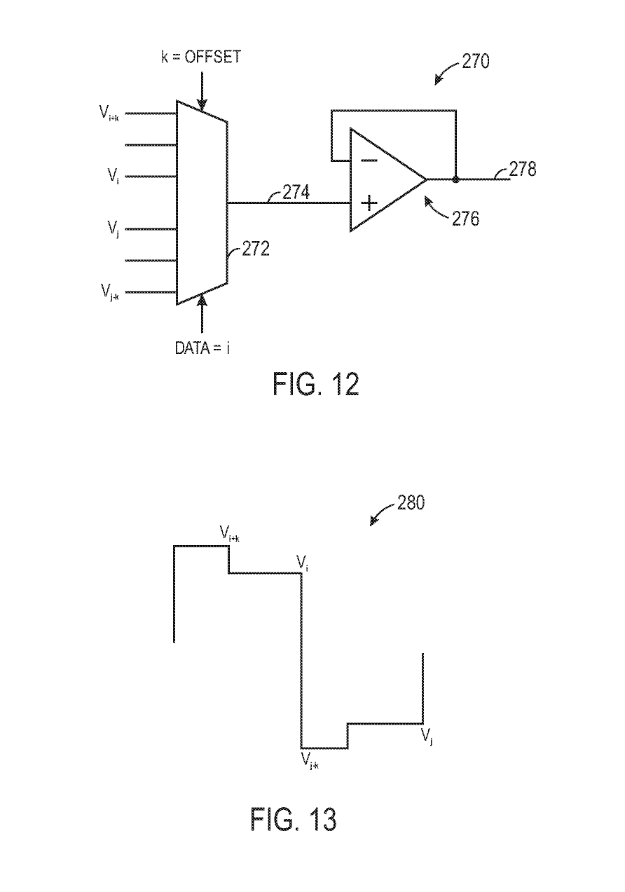

FIG. 12 illustrates a diagram of an analog equivalent circuit 82c to the clock generator discussed in FIG. 9. A signal 280 produced by the analog clock generator 82c is illustrated in FIG. 13. The analog clock generator 82c may include a multiplexer 272 configured to select various voltage levels. The multiplexer output 274 may be input into an amplifier 276, which may produce a clock signal output 278, such as the signal 280. The input Vᵢ₊ₖ of the multiplexer 272 may produce an output 278 of a pre-emphasized portion of the signal 280 (FIG. 13), and the input Vᵢ may produce an output 278 having the voltage level of a logic high of the output clock signal 278. The input Vⱼ may be the voltage of a logic low of the output clock signal 278, and the input Vⱼ₋ₖ may produce a voltage level below that of the low logic voltage Vⱼ. For example, in some embodiments, the input Vⱼ₋ₖ may be combined with input Vᵢ to create a de-emphasized portion of a clock signal.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A method of transmitting signals over a synchronous bus of an electronic device, the method comprising:
transmitting signals from a controller to circuitry of the electronic device over a synchronous bus, wherein transmitting the signals includes pre-emphasizing a first subset of the signals based on a first transmission distance between the controller and a portion of the circuitry receiving each respective signal of the first subset.

2. The method of claim 1, wherein transmitting signals includes de-emphasizing a second subset of the signals based on a second transmission distance between the controller and a portion of the circuitry receiving each respective signal of the second subset.

3. The method of claim 2, wherein the second transmission distance between the controller and the portion of the circuitry receiving each respective signal of the second subset is less than the first transmission distance between the controller and the portion of the circuitry receiving each respective signal of the first subset.

4. The method of claim 2, wherein the de-emphasized signal comprises a first rising edge and a second rising edge, wherein the first rising edge rises to a first voltage and the second rising edge rises to a second voltage higher than the first voltage.

5. The method of claim 2, wherein transmitting signals includes transmitting neutral signals for a third subset of the signals based on a third transmission distance between the controller and a portion of the circuitry receiving each respective signal of the third subset.

6. The method of claim 5, wherein the third transmission distance between the controller and the portion of the circuitry receiving each respective signal of the third subset is less than the first transmission distance between the controller and the portion of the circuitry receiving each respective signal of the first subset and more than the second transmission distance between the controller and the portion of the circuitry receiving each respective signal of the second subset.

7. The method of claim 1, wherein the pre-emphasized signal comprises a rising edge and a falling edge, and wherein the rising edge rises to a first voltage and the falling edge falls from a second voltage lower than the first voltage.

8. A method comprising:
generating a pre-emphasized signal driven to a far region of driving circuitry coupled to data lines for driving pixels of a display;
generating a de-emphasized signal driven to a near region of driving circuitry coupled to data lines for driving pixels of the display; and
generating a neutral signal driven to an intermediate region of driving circuitry coupled to data lines for driving pixels of a display.

9. The method of claim 8, wherein generating the pre-emphasized signal comprises outputting a pre-emphasized voltage output at a rising edge of the pre-emphasized signal before outputting a neutral voltage output, wherein the pre-emphasized voltage output is higher than the neutral voltage output.

10. The method of claim 9, wherein the pre-emphasized signal comprises a pre-emphasized clock signal, and wherein data latched according to the pre-emphasized clock signal is driven by the far region of driving circuitry to data lines corresponding to the far region of driving circuitry.

11. The method of claim 8, wherein generating the de-emphasized signal comprises outputting a de-emphasized voltage output at a rising edge of the de-emphasized signal before outputting a neutral voltage output, wherein the de-emphasized voltage output is lower than the neutral voltage output.

12. The method of claim 11, wherein the de-emphasized signal comprises a de-emphasized clock signal, and wherein data latched according to the de-emphasized clock signal is driven by the near region of driving circuitry to data lines corresponding to the near region of driving circuitry.

13. The method of claim 8, wherein the neutral signal comprises a neutral clock signal, and wherein data latched according to the neutral clock signal is driven by the intermediate region of driving circuitry to data lines corresponding to the intermediate region of driving circuitry.

14. An electronic system comprising:
a synchronous bus; and
control logic configured to transmit signals to circuitry over the synchronous bus, wherein the signals comprise a waveform substantially similar to: 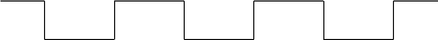
transmitted to the circuitry along a first portion of the synchronous bus, and a waveform having a higher initial voltage and being substantially similar to: 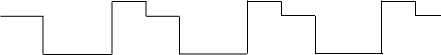
transmitted to the circuitry along a second portion of the synchronous bus.

15. The system of claim 14, wherein the control logic is configured to transmit signals comprising a waveform having a lower initial voltage and being substantially similar to: 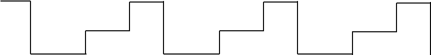
transmitted to the circuitry along a third portion of the synchronous bus.

16. The system of claim 15, wherein the third portion of the synchronous bus is nearest to the control logic, the second portion of the synchronous bus is farthest from the control logic, and the first portion of the synchronous bus is between the third portion and the second portion.

17. The system of claim 15, comprising driving circuitry configured to drive a plurality of data lines, wherein the control logic is configured to generate the waveform substantially similar to: 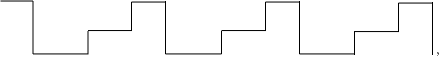
the waveform substantially similar to: 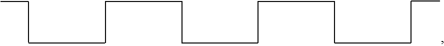
and the waveform substantially similar to: 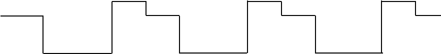
based on the location along the synchronous bus from which data is to be latched by the driving circuitry.

18. The system of claim 15, wherein the control logic includes a clock generator comprising a first transistor and a second transistor coupled in series to one another in parallel to a third transistor and a fourth transistor also coupled in series to one another, wherein the clock generator includes an input node between the first and second transistors and an output node between the third and fourth transistors.

19. The system of claim 18, wherein the series of the first and second transistors and the series of the third and fourth transistors are each coupled in parallel between a supply voltage line and a ground.

20. The system of claim 18, wherein drawing the input node low and deactivating the third transistor and the fourth transistor produces the waveform substantially similar to:

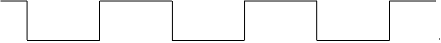

21. The system of claim 18, wherein drawing the input node low and activating the third transistor and deactivating the fourth transistor produces the waveform substantially similar to:

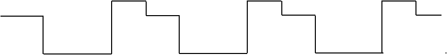

22. The system of claim 18, wherein drawing the input node low and deactivating the third transistor and activating the fourth transistor produces the waveform substantially similar to:

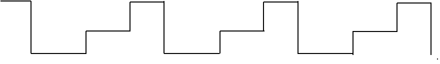

23. Control logic comprising:
a clock generator configured to output one of a plurality of input voltages, wherein the plurality of input voltages comprises:
a first voltage;
a second voltage lower than the first voltage;
a third voltage lower than the second voltage; and
a fourth voltage lower than the third voltage,
wherein the control logic is configured to multiplex more than one of the first voltage, the second voltage, the third voltage, and the fourth voltage to modify the waveform of the transmitted signals.

24. The system of claim 23, wherein the clock generator is configured to output a pre-emphasized clock signal comprising a repeating sequence of the first voltage, followed by the second voltage, followed by the third voltage.

25. The system of claim 23, wherein the clock generator is configured to output a neutral clock signal comprising a repeating sequence of the second voltage followed by the third voltage.

26. The system of claim 23, wherein the clock generator is configured to output a de-emphasized clock signal comprising a repeating sequence of the fourth voltage, followed by the second voltage, followed by the third voltage.

27. A system comprising:
means for generating a pre-emphasized clock signal for a data signal driven to a far region of driving circuitry coupled to data lines for driving pixels of a display;
means for generating a de-emphasized clock signal for a data signal driven to a near region of driving circuitry coupled to data lines for driving pixels of the display; and
means for generating a neutral clock signal for a data signal driven to an intermediate region of driving circuitry coupled to data lines for driving pixels of a display.

28. The system of claim 27, wherein the data signal driven to the near region of driving circuitry is driven from a first portion of a synchronous bus, the data signal driven to the intermediate region of the driving circuitry is driven from a second portion of the synchronous bus, and the data signal driven to the far region is driven from a third portion of the synchronous bus, wherein the first portion precedes the second portion and the second portion precedes the third portion.
